(19) United States
(12) Patent Application Publication
(10) Pub. No.: US 2007/0207267 A1
(43) Pub. Date: Sep. 6, 2007

(54) Disposable liners for etch chambers and etch chamber components

(76) Inventor: David P. Laube, Mesa, AZ (US)

Correspondence Address: THE BOC GROUP, INC., 575 MOUNTAIN AVENUE, MURRAY HILL, NJ, 07974-2064, US

(21) Appl. No.: 11/703,417

(22) Filed: Feb. 7, 2007

Related U.S. Application Data
(60) Provisional application No. 60/771,583, filed on Feb. 8, 2006.

(51) Int. Cl. B05D 7/22; C23C 16/00; H01L 21/306; C25D 11/04

(52) U.S. Cl. 427/230; 205/324; 118/715; 156/914; 156/916; 156/345.1

(57) ABSTRACT

Disposable liners for shielding semiconductor reactor chamber components from erosion in the reactor chamber. More specifically, disposable metal liners and a method of forming such liners wherein the disposable liners have a dielectric material on a surface of the liners to protect semiconductor reactor chamber components from erosion. The disposable liners are formed from a metal sheet that conforms to a surface of a chamber component wherein the metal sheet is subsequently oxidized in an electrolyte free from contaminants using plasma electrolytic oxidation.

This application claims priority from U.S. Provisional Patent Application No. 60/771,583 filed Feb. 8, 2006.

### FIELD OF THE INVENTION

The invention relates to disposable liners for shielding semiconductor reactor chamber components from erosion in the reactor chamber. More specifically, the invention relates to disposable metal liners having a dielectric material on a surface of the liners to protect semiconductor reactor chamber components from erosion. The invention also provides a method of forming the disposable liners.

### BACKGROUND OF THE INVENTION

Reactor chambers, such as etch and CVD reactors used in semiconductor device manufacturing, tend to build up deposits on the interior surfaces of the chambers as a function of wafer throughput. These deposits build in thickness until they begin to flake and generate particles that lead to defects on the wafer. As part of the manufacturing process, in situ nitrogen fluoride or other fluorine-containing compounds are used to generate a plasma to periodically clean the reactor chamber and to reduce particle contamination. However, eventually this plasma cleaning becomes less effective to prevent or reduce particle contamination and the chamber components must be removed for cleaning and refurbishment.

Current chamber designs utilize chamber components that must be completely removed from the chamber for cleaning and refurbishment. Such components are replaced with a spare set of new or refurbished components to maximize tool up-time. Not only is it costly and time consuming to remove chamber components, the components are typically very expensive which limits the number of replacement components an end user will maintain on-site.

For etch tools, chamber components are fabricated from ceramic, quartz or anodized aluminum materials that are designed to withstand aggressive plasma and/or reactive chemical species that degrade component surfaces and critical features of the components. These components degrade with each cleaning cycle until such a point where the components are no longer usable and must be replaced.

Often a chamber component is anodized to form a corrosion resistant coating on its surface which increases the useable lifetime of the component. Hard coat anodizing (e.g. conventional sulfuric acid processing) is one method of forming a protective coating on the surface of a chamber component to protect the component from chemical or plasma erosion in the reactor chamber. During a hard coat anodizing process, a cathode and the component are immersed a chilled sulfuric acid electrolyte having a concentration of about 10 to 20 wt % H₂SO₄. The component is configured to be the anode of the process and it forms an oxide coating on its surface as the process proceeds. The current density is typically maintained between 30 and 90 A/ft² while the voltage is maintained between 30 and 90 V. For an aluminum substrate, a hard coat anodizing process creates a coating of aluminum oxide having a thickness of 50 to 150 μm. While the hard coat anodizing process is particularly useful for anodizing thick metal components, the process is insufficient to coat thin metals having a thickness of less than about 0.030 inches because the hard coat anodizing process will burn through such thin metals.

A plasma electrolytic oxidation process, as described in U.S. Pat. No. 6,896,785 B2 issued to Isle Coat, Ltd., may also be used to form an oxide coating on metals and alloys. Like the hard coat anodizing process, a cathode and the article to be coated are immersed in an electrolyte wherein the article forms the anode of the process. The electrolyte is of the aqueous and alkaline type and consists of colloid solutions which are preferably made from nanopowders. The following nanopowders may be added to the electrolyte: oxides and mixtures thereof (e.g. Al₂O₃, ZrO₂, CeO₂, CrO₃, MgO, SiO₂, TiO₂, Fe₂O₃, Y₂O₃), borides (ZrB₂, TiB₂, CrB₂, LaB₂), nitrides (Si₃N₄, TiN, AlN, BN), carbides (B₄C, SiC, Cr₃C₂, TiC, ZrC, TaC, VC, WC), sulfides (MOS₂, WS₂, ZnS, CoS) and silicides (WSi₂, MoSi₂). Examples of known electrolytes used in the plasma electrolytic oxidation process include a phosphate-silicate electrolyte (pH 9-11), a phosphate-aluminate electrolyte (pH 12.5), and a phosphate-borate electrolyte (pH 9-9.5). A ceramic coating is formed on the article when a high-frequency bipolar pulsed current having a predetermined frequency range is supplied across the electrodes and acoustic vibrations are generated in the electrolyte at a predetermined sonic frequency range. The pulsed current is supplied across the electrodes so as to enable the process to be conducted in a plasma-discharge regime. The pulsed current is created in a bath with a pulse succession frequency of 500 Hz or more and preferably 1,000 to 10,000 Hz with a duration of 20 to 1,000 μsec. The current density is typically 3 to 200 A/dm². The frequency range of the acoustic vibrations is selected to overlap with the frequency range of the current pulses.

The plasma electrolytic oxidation process makes it possible to form corrosion-resistant ceramic coatings on metal and alloy surfaces wherein the coatings are characterized by a high degree of uniformity of thickness, low surface roughness and virtually no external porous layer. However, the known electrolytes used in the plasma electrolytic oxidation process produce coatings containing materials which are undesirable in semiconductor reactor chamber environments.

### SUMMARY OF THE INVENTION

In a first aspect, the invention is directed to a method of producing disposable liners for internal chamber components or internal walls of reactor chambers comprising the steps of: forming a metal sheet to conform to a surface of the internal wall or the chamber component; and coating a surface of the liner with a dielectric material for protecting the internal walls or chamber components from erosion when exposed to the reactor chamber environment.

In another aspect, the invention is directed to a method of forming a disposable liner for a semiconductor reactor chamber component comprising: forming a metal sheet to conform to a surface of the component; and forming a dielectric coating on a surface of the metal sheet by using plasma electrolytic oxidation.

A liner for use as a disposable shield for internal walls or chamber components exposed to reactor chambers, comprising: an aluminum sheet to conform to a surface of the internal wall or chamber component; and a dielectric material coating on a surface of the aluminum sheet for protecting the internal walls or chamber components from erosion when exposed to the reactor chamber environment.

A disposable liner for a semiconductor reactor chamber component comprising: a metal sheet to conform to a surface of the component; and a dielectric coating on a surface of the metal sheet for protecting the component from erosion when exposed to the reactor chamber environment.

### BRIEF DESCRIPTION OF THE DRAWINGS

FIG. 1a is a drawing of one embodiment of a first step for forming the metal into a liner according to the present invention.

FIG. 1b is a drawing of one embodiment of a second step for forming the metal into a liner according to the present invention.

FIG. 1c is a drawing of an embodiment of the liner according to the present invention.

### DETAILED DESCRIPTION OF THE INVENTION

To overcome the disadvantages relating to: 1) the practice of removing, storing and replacing chamber components; 2) the hard coat anodizing process; and 3) the plasma electrolytic oxidation process, the present invention provides disposable liners and a method of manufacturing disposable liners for internal components and surfaces of reactor chambers (e.g. etch and CVD chambers) used in semiconductor device manufacturing processes. The present invention also discloses a method of using thin metal, disposable liners to protect the reusable chamber components from deposit buildup and/or erosion. The present invention further discloses a thin metal, disposable liner for reactor chamber components wherein the liner has superior properties for use in semiconductor manufacturing processes as compared to conventional dielectric coatings on chamber components.

One primary advantage of the present invention is that the liners may be easily inserted and removed from the chamber without having to remove the chamber components. This reduces the amount of time that a reactor chamber is off-line and unproductive during servicing. In addition, because the liners protect the chamber components, the period between refurbishment of the components is extended thereby reducing the manufacturing costs associated with periodic refurbishment. Moreover, the liners are inexpensive to manufacture and do not impose any dimensional interference in the fit and function of the chamber.

According to the present invention, the life of a reactor chamber component may be extended by using a disposable liner to protect the surface of the component. The liner in one embodiment, is made of thin aluminum metal having a dielectric coating that permits the liner and the chamber component to which the liner is conformed to withstand aggressive environments (e.g. plasma and chemical environments) in the reactor chamber.

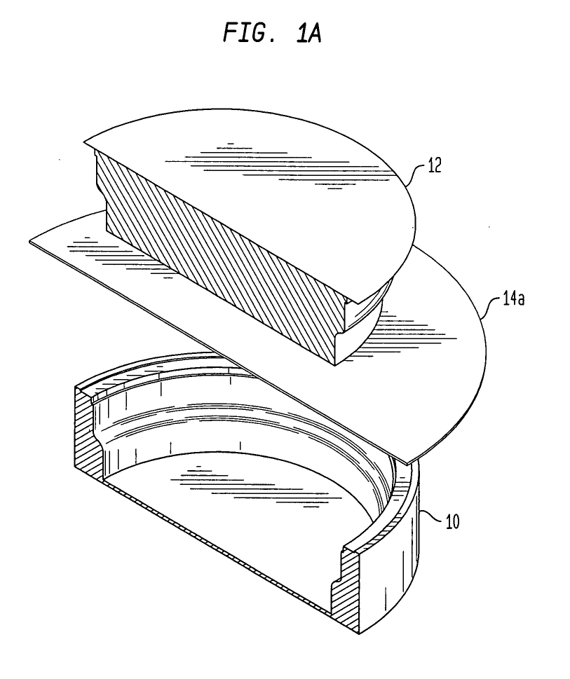

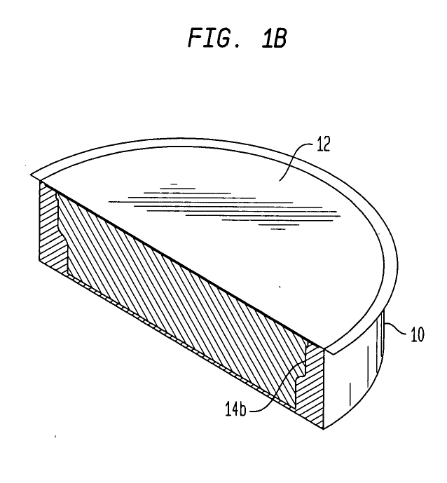

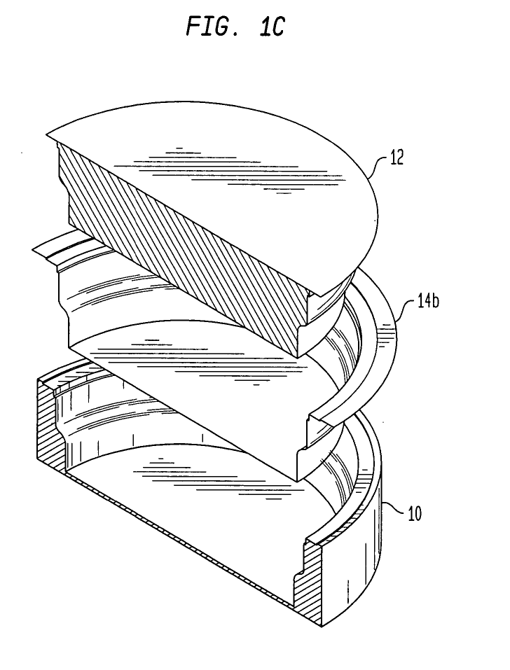

The liner may be manufactured by the following method according to one embodiment the present invention. The method will be described with reference to FIGS. 1a-1c. While the liners may be manufactured using an actual chamber component as the mold, it is preferable to mass produce liners for a chamber component using a mold 10 of the component. The mold 10 is used to manufacture liners having the same geometry and size as the component. The mold 10 is preferably constructed of a hardened tool steel. Preferably the mold 10 is slightly oversized so that the resulting liner will have the same dimensions as the component. In one embodiment, the liner is formed using a mandrel 12. The outer surface of the mandrel 12 must fit within the inner contours of the mold 10 as shown in FIG. 1a. Preferably, the mandrel 12 is sized to leave a small gap between the outer surface of the mandrel 12 and the inner surface of the mold 10.

To form the liner, a thin sheet of metal 14a is placed between the mold 10 and the mandrel 12 as shown in FIG. 1a. Next, the mandrel 12 is moved to apply a downward force against the metal 14a and mold 10, as shown in FIG. 1b. The metal 14a thus conforms to the mold 10 resulting in the formation of the liner 14b as shown in FIG. 1c. The thickness of the metal is preferably from about 0.005 inch to 0.025 inch. Notably, the metal must be thin so that when the liner is placed on the chamber component, the dimensions of the component are not substantially altered which could interfere with, for example, the etch or CVD process. While the liner may be formed from any metal, for semiconductor manufacturing processes, the metal/liner 14 is preferably aluminum or an aluminum alloy. Aluminum forms an aluminum oxide dielectric coating when treated with an electrolytic oxidation process as will be further described below. The aluminum oxide coating has superior chemical, plasma and erosion resistance properties as compared to other dielectric materials. Other metals that form dielectric coatings suitable for semiconductor device manufacturing are titanium or titanium alloys and magnesium or magnesium alloys.

In another embodiment, a hydro forming tool may be used to shape the metal 14a into the liner 14b. Like the mandrel process, the hydro forming process applies a downward force to the metal 14a which thus conforms to the mold 10. However, instead of a mandrel, a bladder is used to apply the downward force. The hydro forming process has the advantage over the mandrel process in that the same bladder may be used for numerous different components, whereas a mandrel would have to be manufactured for each component design.

In another embodiment, the metal may be shaped into the liner using a spinning process. Like the mandrel process, the spinning process also requires a mandrel having the same geometry as the component on which the liner will be placed. The mandrel is preferably undersized slightly as compared to the component for which the liner will be made so that the liner will have the appropriate dimensions. The metal is attached to the mandrel which is configured to rotate about its center axis. As the mandrel and metal spin, the metal is bent and pressed against the mandrel and thus conforms to the shape of the component. Other methods of forming the metal liners include stamping, pressing, and vacuum forming.

Once the liner 14b is formed, the surface of the liner 14b that will be exposed to the reactor environment is treated to form a protective dielectric coating. Prior to exposing the surface to a process for forming the dielectric coating, as will be discussed in detail below, the surface is cleaned with an alkaline cleaning solution and rinsed with deionized water. The surface is then treated with an acid etch solution and once again rinsed with deionized water. Next, the surface is treated using a plasma oxidation (PEO) process to form a unique dielectric coating having desirable properties for semiconductor reactor chamber environments. Once the coating is formed, the liner is rinsed with high purity deionized water.

The dielectric coating is formed on the surface of the liner by subjecting the surface to a PEO process. PEO is particularly useful to form dielectric coatings for use in semiconductor reactor chamber environments. PEO is performed in alkaline solutions where the work piece is made the anode in an electrolytic cell. The liner is immersed in an electrolyte and forms the cathode.

Notably, conventional electrolytes used in conventional PEO processes typically contain materials that are contaminants in semiconductor manufacturing processes. Materials such as fluoride, potassium, phosphorous, sodium, boron, iron, copper, sulfur and calcium are all contaminants that may detrimentally impact the performance of semiconductor devices and thus, such materials must be minimized or eliminated from reactor chambers during semiconductor device manufacturing. In accordance with the present invention, the PEO process is performed using an electrolyte that is free from fluoride, potassium, phosphorous, sodium, boron, iron, copper, sulfur or calcium or materials that may release these substances or cause these substances to be present in the resulting dielectric coating. By controlling the PEO process in this manner, a dielectric coating is formed on the liner having optimal properties for semiconductor reactor chamber environments.

Indeed, the dielectric coating that is produced on the liner has superior properties as compared to dielectric coatings formed using conventional hard coat or PEO processes. Not only is the dielectric coating free from reactor chamber contaminants, but it has a roughness of about 32 Ra to about 300 Ra which promotes mechanical bonding of the deposits to the dielectric coating in the reactor chamber. The thickness of the resulting dielectric coating is from about 10 μm to about 75 μm.

Several experimental tests show the superiority of the dielectric coating of the present invention as compared to convention methods of forming the dielectric coating. The results of an outgassing experiment showed that the total mass loss for a dielectric coating prepared using a conventional hard coat process was 170.192 μg/cm² whereas the total mass loss for the dielectric coating of the present invention was only 2.383 μg/cm². This is a substantial improvement over the prior coatings.

Whereas a conventional hard coat anodizing process utilizes acidic electrolytes and moderate voltages to grow anodic aluminum oxide films, PEO utilizes very high voltage potentials as much as ten times that of conventional hard coat. The high voltage potential creates an oxygen plasma at the work piece-electrolyte interface resulting in the formation of a fused aluminum oxide surface layer. The nature of oxide formation by electrolytic plasma is not columnus and forms a nanocrystalline structure of alpha phase aluminum oxide surrounded by a matrix of amorphous alumina. This structure allows formation of a more conformal coating that is not sensitive to corners and tight radii and reduces failure points for erosion as compared to conventional films.

While PEO is the preferred method for anodizing the liners, in another embodiment, the conventional sulfuric acid processing may be used for thick liners. Similarly, oxalic acid or plating by Keronite®, as well as other coating technologies and combinations of technologies can be utilized to provide the coating to the liners.

While the disposable liner and method of forming a disposable liner according to the present invention may be used for any components, the invention is particularly useful for semiconductor chamber components. Such components include chamber liners, gas distribution plates, focus rings, windows, bellows assembly covers, baffle (exhaust) plates, upper and lower electrodes.

While the foregoing description and drawings represent the preferred embodiments of the present invention, it will be apparent to those skilled in the art that various changes and modifications may be made therein without departing from the true spirit and scope of the present invention.

1. A method of producing disposable liners for internal chamber components or internal walls of reactor chambers comprising the steps of:
forming a metal sheet to conform to a surface of the internal wall or the chamber component; and
coating a surface of the liner with a dielectric material for protecting the internal walls or chamber components from erosion when exposed to the reactor chamber environment.

2. The method of claim 1 wherein the step of forming comprises forming an aluminum sheet.

3. The method of claim 2 wherein the dielectric material comprises aluminum oxide.

4. The method of claim 1 wherein the step of forming comprises hydro forming.

5. The method of claim 1 wherein the step of forming comprises spinning.

6. The method of claim 1 wherein the step of forming comprises vacuum forming.

7. The method of claim 1 wherein the step of coating is a hard coat anodizing process.

8. The method of claim 1 wherein the step of coating is a plasma electrolytic oxidation process.

9. The method as in claim 7 wherein the metal sheet has a thickness greater than 0.030 inch.

10. The method as in claim 8 wherein the metal sheet has a thickness greater than 0.010 inch.

11. The method as in claim 1 wherein the metal sheet comprises titanium.

12. The method as in claim 11 wherein the dielectric material comprises titanium oxide.

13. A method of forming a disposable liner for a semiconductor reactor chamber component comprising:
forming a metal sheet to conform to a surface of the component; and
forming a dielectric coating on a surface of the metal sheet by using plasma electrolytic oxidation.

14. The method of claim 13 wherein the step of forming the metal sheet comprises using a mandrel to apply force to the metal sheet.

15. The method of claim 13 wherein the step of forming the metal sheet comprises hydro forming.

16. The method of claim 13 wherein the step of forming the metal sheet comprises spinning.

17. The method of claim 13 wherein the step of forming the metal sheet comprises forming aluminum or aluminum alloy to conform to a surface of the component.

18. The method of claim 13 wherein the step of forming the metal liner comprises forming titanium or titanium alloy to conform to a surface of the component.

19. The method of claim 13 wherein the step of forming the metal liner comprises forming magnesium or magnesium alloy to conform to a surface of the component.

20. The method of claim 13 wherein the step of forming the metal liner comprises forming the metal liner to conform to a surface of a component selected from the group of components consisting of chamber liners, gas distribution plates, focus rings, windows, bellows assembly covers, baffle plates, upper electrodes, and lower electrodes.

21. The method of claim 13 wherein the step of forming the dielectric coating comprises immersing the metal liner in an electrolyte that is substantially free of fluoride, potassium, phosphorous, sodium, boron, iron, copper, sulfur or calcium or materials that may produce these substances.

22. A liner for use as a disposable shield for internal walls or chamber components exposed to reactor chambers, comprising:
an aluminum sheet to conform to a surface of the internal wall or chamber component; and
a dielectric material coating on a surface of the aluminum sheet for protecting the internal walls or chamber components from erosion when exposed to the reactor chamber environment.

23. The liner as in claim 22 wherein the dielectric material is aluminum oxide.

24. The liner as in claim 22 wherein the aluminum sheet has a thickness greater than 0.030 inch.

25. The liner as in claim 22 wherein the aluminum sheet has a thickness greater than 0.010 inch.

26. The liner as in claim 22 wherein the coating is applied by a hard coat anodizing process.

27. The liner as in claim 25 wherein the coating is applied by a plasma electrolytic oxidation process.

28. A disposable liner for a semiconductor reactor chamber component comprising:
a metal sheet to conform to a surface of the component; and
a dielectric coating on a surface of the metal sheet for protecting the component from erosion when exposed to the reactor chamber environment.

29. The disposable liner of claim 28 wherein the metal sheet comprises aluminum or aluminum alloy.

30. The disposable liner of claim 28 wherein the metal sheet comprises titanium or titanium alloy.

31. The disposable liner of claim 28 wherein the metal sheet comprises magnesium or magnesium alloy.

32. The disposable liner of claim 28 wherein the component is selected from the group of components consisting of chamber liners, gas distribution plates, focus rings, windows, bellows assembly covers, baffle plates, upper electrodes, and lower electrodes

33. The disposable liner of claim 28 wherein the dielectric coating comprises aluminum oxide.

34. The disposable liner of claim 28 wherein the dielectric coating comprises titanium oxide.

35. The disposable liner of claim 28 wherein the dielectric coating comprises magnesium oxide.

36. The disposable liner of claim 33 wherein the aluminum oxide coating comprises a nanocrystalline structure of alpha phase aluminum oxide surrounded by a matrix of amorphous alumina.

37. The disposable liner of claim 28 wherein the dielectric coating has a roughness of about 32 Ra to about 300 Ra.

38. The disposable liner of claim 28 wherein the dielectric coating has a thickness of about 10 μm to about 75 μm.
